(19) United States
(12) Patent Application Publication
(10) Pub. No.: US 2026/0039274 A1
(43) Pub. Date: Feb. 5, 2026

(54) Substrate, Electronic Device, and Module

(71) Applicant: QUANZHOU SANAN INTEGRATED CIRCUIT CO.,LTD., Quanzhou (CN)

(72) Inventors: Minghui FANG, Quanzhou (CN); Wenbi CAI, Quanzhou (CN); Zhonghe LIN, Quanzhou (CN); Shihwei HUANG, Quanzhou (CN); Yilin LIU, Quanzhou (CN)

(21) Appl. No.: 19/274,213

(22) Filed: Jul. 18, 2025

(30) Foreign Application Priority Data
Aug. 1, 2024 (CN) 2024110460429

(51) Int. Cl. H03H 9/02; H03H 9/145

(52) U.S. Cl. CPC H03H 9/02574; H03H 9/02551; H03H 9/02559; H03H 9/02897; H03H 9/14552

(57) ABSTRACT

The present invention discloses a substrate, an electronic device, and a module. The substrate provided by embodiments comprises a carrier substrate formed of a polycrystalline material, wherein the carrier substrate has a grain density greater than or equal to 1000 grains/mm²; and a grain boundary volume fraction ranging from 8% to 40%. The disclosed carrier substrate having such a specific grain density achieves high mechanical strength, which reduces the likelihood of chipping due to insufficient strength, thereby ensuring production quality and efficiency.

### CROSS-REFERENCE TO RELATED APPLICATION

The present disclosure claims priority to Chinese Patent Application No 2024110460429 filed Aug. 1, 2024, the contents of which are herein incorporated by reference in its entirety.

### FIELD

This application relates to the field of mobile communication devices and, more particularly, to a substrate, an elastic wave device and a communication module including the elastic wave device.

### BACKGROUND

In certain acoustic wave filters, such as surface acoustic wave (SAW) devices, and more specifically in temperature-compensated SAW (TC-SAW) filters, a composite substrate formed by bonding a piezoelectric layer to a carrier substrate is required Among the parameters of the carrier substrate, mechanical strength is one of the most important in the manufacturing of SAW devices. If the strength of the carrier substrate is insufficient, chipping may occur during subsequent manufacturing steps, such as the bonding process or the formation of electrodes on the composite substrate, leading to reduced production yield and quality, and potentially increasing overall manufacturing costs.

### SUMMARY

Some examples described herein may have an object to provide a substrate which is capable of achieving high strength, addressing the issue of fragmentation that can occur due to insufficient strength of the substrate, thereby ensuring product quality and manufacturing efficiency.

In some examples, a substrate is provided, comprising a carrier substrate which formed of a polycrystalline material, wherein the carrier substrate has a grain density of greater than or equal to 1000 grains/mm², and a grain boundary volume ratio of 8% to 40%.

In some examples, an electronic device is provided, which comprising a substrate comprising a carrier substrate which formed of a polycrystalline material, wherein the carrier substrate has a grain density of greater than or equal to 1000 grains/mm², and a grain boundary volume ratio of 8% to 40%; a piezoelectric layer disposed over the carrier substrate; and an IDT electrode provided on a principal surface of the piezoelectric layer opposite to the carrier substrate.

In some examples, a module is provided that includes a wiring substrate, a plurality of external connection terminals, an integrated circuit component, an inductor, a sealing portion, and the above-described electronic device.

The embodiments of this invention provide at least one or more of the following advantageous effects: By providing a support substrate having a specific grain density, enhanced flexural strength can be achieved, which prevents chipping during subsequent bonding processes, thereby ensuring both production quality and efficiency.

Details of one or more embodiments of the present application are set forth in the accompanying drawings and the description below. Other features, objects, and advantages of the present application will become apparent from the description and drawings, and from the claims.

### BRIEF DESCRIPTION OF THE DRAWINGS

The accompanying drawings are intended to provide a further understanding of the present application, constitute part of this application, and illustrate exemplary embodiments of this application. The description and drawings do not limit the scope of the application.

FIG. 1 is a schematic diagram showing the structure of a carrier substrate according to one embodiment.

FIG. 2 is a microstructural image of the carrier substrate provided in the embodiment FIG. 3 is a schematic diagram showing the structure of the composite substrate.

FIG. 4 is a schematic diagram showing an electronic device according to the first embodiment.

FIG. 5 is a schematic diagram showing an electronic device according to the second embodiment.

FIG. 6 is a schematic diagram showing an electronic device according to the third embodiment.

FIG. 7 is a schematic diagram showing an electronic device according to the fourth embodiment.

FIG. 8 is a schematic diagram showing a module according to one embodiment.

FIG. 9 is a schematic view of a designated region for yield testing of the electronic device.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

In order to make the objectives, features, and advantages of the present invention more clearly understood, specific embodiments of the invention are described in detail below with reference to the accompanying drawings.

To facilitate a better understanding of the technical solutions of the invention for those skilled in the art, the following descriptions of the embodiments of the invention are provided clearly and comprehensively with reference to the accompanying drawings It should be understood that the described embodiments are only part of the invention and not exhaustive All other embodiments obtained by those skilled in the art without involving inventive activity, based on the disclosed embodiments, shall fall within the scope of protection of the invention.

It should also be noted that the terms “first,” “second,” and so on, used in the specification, claims, and drawings of the invention, are merely to distinguish similar elements and do not imply a particular sequence or order These terms can be used interchangeably when appropriate, so that the embodiments of the invention can be implemented in sequences other than those illustrated or described Furthermore, the terms “include”, “comprise” and variations thereof are intended to be non-exclusive For example, a process, method, system, product, or apparatus that comprises a series of steps or elements is not limited to only those explicitly listed but may also include other steps or elements that are inherent or not expressly stated.

Additionally, it should be noted that the division of embodiments in this disclosure is made for ease of explanation and should not be interpreted as limiting Features of the various embodiments may be combined or referenced where there is no conflict.

### First Embodiment

A method for manufacturing a carrier substrate is provided. The resulting carrier substrate includes a main supporting surface configured to support a piezoelectric layer and a back surface opposite to the main supporting surface.

The method for manufacturing the carrier substrate comprises:
Step S11: forming a crystal ingot using raw crystalline powder and processing the ingot into a pre-processed substrate;
Step S12: polishing both opposite surfaces of the pre-processed substrate;
Step S13: performing sandblasting on one of the polished surfaces of the pre-processed substrate to obtain the carrier substrate.

The raw crystalline powder in Step S11 may be a powder of a polycrystalline material, such as polycrystalline magnesium aluminum spinel, polycrystalline sapphire, polycrystalline aluminum nitride, polycrystalline magnesium oxide, or polycrystalline quartz. In Step S11, techniques such as Cold Isostatic Pressing (CIP) or Hot Isostatic Pressing (HIP) may be used to form the ingot, followed by cutting and grinding to obtain the pre-processed substrate.

For example, in Step S12, the two polished surfaces of the pre-processed substrate are referred to as first and second surfaces, respectively. The first surface is used as the main supporting surface for the piezoelectric layer in subsequent processes. In Step S12, the first surface is polished to achieve an arithmetic mean roughness (Sa) of less than or equal to 0.6 nm, ensuring optimal bonding integrity with the piezoelectric layer. Surface roughness characterization in this specification follows ISO 25178 metrics, including:

Sa (Arithmetic mean height) Sz (Maximum height)

Sq (Root mean square height)

Sp (Maximum peak height).

In the first embodiment, after Step S12, the pre-processed substrate exhibits a Total Thickness Variation (TTV)≤1 μm, thereby minimizing any adverse effect on the thickness uniformity of the piezoelectric layer in subsequent processing.

Step S13 involves sandblasting the second surface of the pre-processed substrate, which becomes the back surface of the carrier substrate. The sandblasting process breaks through the grains on the second surface of the pre-processed substrate, thereby roughening it and enabling the back surface 112 of the carrier substrate to achieve a target surface roughness (Sz) as defined in ISO 25178.

In the first embodiment, both opposite surfaces of the pre-processed substrate are polished, after which the surface that eventually becomes the carrier substrate's back surface is sandblasted to roughen it, and this approach achieves a low total thickness variation (TTV) while reducing the optical transmittance of the resulting carrier substrate. As a result, alignment issues during subsequent processing can be avoided even with minimized TTV.

This embodiment further provides a method for fabricating a composite substrate comprising a carrier substrate and a piezoelectric layer, with the piezoelectric layer disposed on the main support surface of the carrier substrate.

The method comprises the following steps:
Step S11: forming an crystal ingot from raw crystalline powder and processing it into a pre-processed substrate;
Step S12: polishing both opposite surfaces of the pre-processed substrate;
Step S14: bonding the polished pre-processed substrate with a piezoelectric wafer; and
Step S15: sandblasting the surface of the polished pre-processed substrate that is opposite the piezoelectric wafer to form the composite substrate.

Specifically, Steps S11 and S12 follow the detailed procedures previously described for manufacturing the carrier substrate. In Step S14, the piezoelectric wafer may be produced by slicing, grinding, polishing, and reduction processing of a lithium tantalate ingot to form a finished piezoelectric substrate. Optionally, Step S16 may precede S15, in which the piezoelectric wafer is thinned and polished to obtain a piezoelectric layer of a target thickness (e.g. 3 μm). Because the TTV of the pre-processed substrate after polishing in Step S12 can be maintained at ≤1 μm, the piezoelectric layer in Step S16 may be controlled to 3±0.3 μm (2.7 μm˜3.3 μm range). Step S15 is analogous to Step S13 but is performed after bonding; the back surface formed by sandblasting becomes the back surface of the carrier substrate.

In this embodiment, the composite substrate fabrication method not only delivers low TTV through dual-sided polishing (Step S12), but also lowers optical transmittance through subsequent sandblasting (Step S15), thereby preventing alignment difficulties during downstream processing while preserving low TTV. Moreover, since the previously sandblasted back surface already exhibits the desired roughness, no further thinning of the carrier substrate is required after bonding, which helps to maintain a low level of warpage. Consequently, in the composite substrate, the warpage of the carrier substrate can be kept to ≤200 μm, widening the process window for subsequent packaging processes.

### Second Embodiment

In conventional composite substrate fabrication using separate support and piezoelectric substrates, if the carrier substrate is too thin, breakage may occur during bonding, necessitating the use of thick carrier substrates that are later thinned from the back However, thinning introduces residual stress, and if the remaining thickness becomes too low, warpage increases, impairing automated handling during packaging. Therefore, conventional practice typically maintains a post-thinning carrier substrate thickness above 300 μm, limiting further thinning.

The second embodiment overcomes this limitation by enabling fabrication of much thinner carrier substrates-below 300 μm-without breakage risk during bonding or processing. If one were to simply use a conventional carrier substrate thinner than 300 μm, or to thin a standard substrate below 300 μm, the mechanical strength would be insufficient, and breakage during bonding or later processing would be likely.

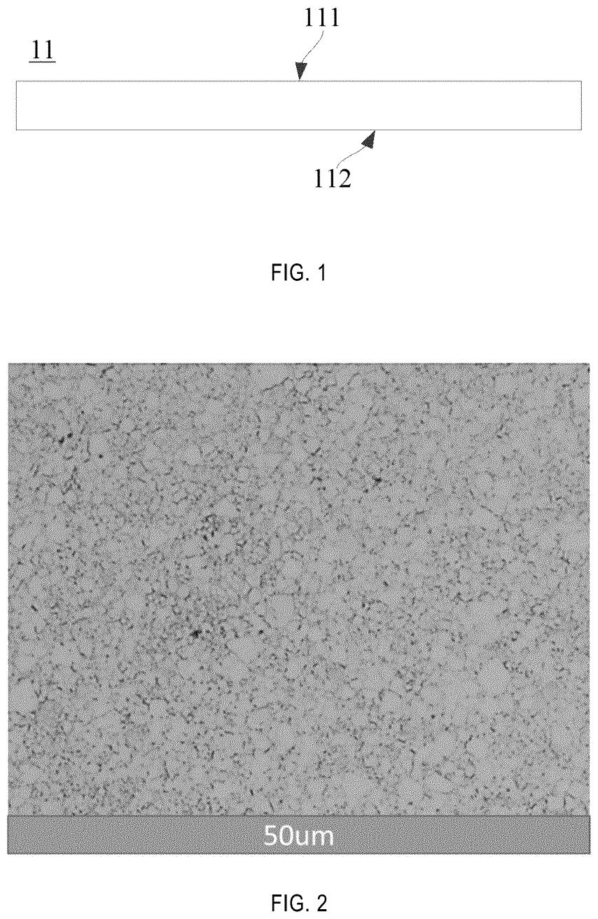

To address this, this embodiment provides a carrier substrate with enhanced strength. FIGS. 1 and 2 illustrate a carrier substrate in this embodiment: FIG. 1 shows the structural schematic, and FIG. 2 presents a microstructural image of a 50 μm×50 μm region.

The carrier substrate is formed of a polycrystalline material such as magnesium aluminum spinel, sapphire, aluminum nitride, magnesium oxide, or quartz, and comprises numerous grains. The grain density may be at least 1000 grains/mm², and potentially 2000; 20000; 80000; or even 250000 grains/mm², with a minimum of 1000 grains/mm². The corresponding grain-boundary volume fraction is in the range of 8-40%, as determined via electron backscatter diffraction (EBSD). By engineering both grain density and grain-boundary volume fraction within these ranges, this embodiment achieves a carrier substrate with higher flexural strength, thus preventing breakage during bonding and ensuring production efficiency and quality.

Grain density is determined by counting the total number of grains N within a specified surface region and dividing by the area of that region S (in mm²), such that N/S≥1000 grains/mm². Practically, larger surface areas are subdivided into smaller regions (eg, 50 μm×50 μm), and the grain counts are summed to calculate grain density.

Grain boundaries refer to interfaces between adjacent grains of differing crystal orientation. Grain-boundary volume fraction is defined as the volume of grain boundaries divided by the total volume of a region If V₀ is the total volume and V₁ is the summed volume of grains, then the grain-boundary volume is V₂=V₀−V₁, and the volume fraction is (V₀−V₁)/V₀, which can be measured using EBSD. For example, grain-boundary volume fractions may be 10%, 15%, 20%, 30%, 35%, or 40%. By designing this parameter appropriately, a carrier substrate with optimal mechanical strength is obtained.

Referring to FIG. 1, the carrier substrate 11 includes a main support surface 111 and a back surface 112 opposite to the main support surface 111. The main support surface 111 is configured to support a piezoelectric layer. The thickness of the carrier substrate 11 refers to the distance between the main support surface 111 and the back surface 112. Table 1 records data on grain density, grain boundary volume fraction, thickness, and corresponding flexural strength of several examples of the carrier substrate 11 provided in the second embodiment. In this disclosure, the flexural strength is measured using a bending test machine provided by Jinan Zhongchuang Industrial Testing System Co., Ltd. The grain density typically has a fluctuation of about 10%.

TABLE 1

| | | Grain Boundary | | Flexural |
|---|---|---|---|---|
| Experimental | Grain Density | Volume Ratio | Thickness | Strength |
| No. | (grains/mm²) | (%) | (μm) | (MPa) |
| 1 | ≥200 | ≈6% | 300 | 186 |
| 2 | ≥200 | ≈6% | 250 | 165 |
| 3 | ≥200 | ≈6% | 200 | 143 |
| 4 | ≥1000 | ≈8% | 300 | 235 |
| 5 | ≥1000 | ≈8% | 250 | 202 |
| 6 | ≥1000 | ≈8% | 200 | 161 |
| 7 | ≥2000 | ≈8% | 300 | 246 |
| 8 | ≥2000 | ≈8% | 250 | 207 |
| 9 | ≥2000 | ≈8% | 200 | 163 |
| 10 | ≥20000 | ≈10% | 300 | 351 |
| 11 | ≥20000 | ≈10% | 250 | 248 |
| 12 | ≥20000 | ≈10% | 200 | 185 |
| 13 | ≥80000 | ≈18% | 300 | 363 |
| 14 | ≥80000 | ≈18% | 250 | 268 |
| 15 | ≥80000 | ≈18% | 200 | 201 |
| 16 | ≥250000 | ≈25% | 300 | 355 |
| 17 | ≥250000 | ≈25% | 250 | 270 |
| 18 | ≥250000 | ≈25% | 200 | 219 |

As shown in Table 1, under constant grain density, the flexural strength increases with increasing thickness. Referring to Experimental Nos. 1-3, when the grain density is approximately 200 grains/mm² and the grain boundary volume fraction is approximately 6%, a thickness greater than 300 μm is required to achieve a flexural strength of over 180 MPa. In contrast, referring to Experimental Nos. 4-6, when the grain density is approximately 1000 grains/mm² and the grain boundary volume fraction is about 8%, a thickness of 250 μm is sufficient to exceed 200 MPa. As indicated by Experimental No. 12, when the grain density is around 20000 grains/mm² and the grain boundary volume fraction is about 8%, the carrier substrate 11 can still achieve a flexural strength exceeding 180 MPa even with a thickness reduced to 200 μm.

Furthermore, comparing Experimental Nos. 3, 6, 9, 12, and 15, it can be seen that under the same thickness, a grain density of approximately 80000 grains/mm² allows the flexural strength of the carrier substrate 11 to exceed 200 MPa. Therefore, the carrier substrate 11 provided by the second embodiment exhibits superior flexural strength, which can prevent chipping during subsequent bonding processes, thereby ensuring production quality and efficiency.

According to the experimental results in Table 1, in some embodiments, the thickness of the carrier substrate 11 is less than or equal to 300 μm. For example, the thickness of the carrier substrate 11 may be 300 μm, 250 μm, or 200 μm. More specifically, the thickness of the carrier substrate 11 is less than or equal to 200 μm, for example, 200 μm, 180 μm, or 150 μm. By reducing the thickness of the carrier substrate 11 while ensuring production quality, improved heat dissipation of the product can be achieved.

In some embodiments, the flexural strength of the carrier substrate 11 is greater than or equal to 180 MPa, which can prevent chipping. For example, the flexural strength of the carrier substrate 11 may be 180 MPa, 200 MPa, or 250 MPa.

In some embodiments, the grain density of the carrier substrate 11 is greater than or equal to 80000 grains/mm², and the flexural strength of the carrier substrate 11 is greater than or equal to 200 MPa. Such characteristics ensure sufficient strength even when the substrate is fabricated to be thinner, maintaining production quality while meeting heat dissipation requirements.

In some embodiments, the Young's modulus of the carrier substrate 11 is greater than or equal to 250 GPa. The Young's modulus describes the material's resistance to deformation; therefore, a value greater than or equal to 250 GPa provides enhanced mechanical strength.

In some embodiments, the grain size of the grains in the carrier substrate 11 is specifically 10 μm or less.

The second embodiment of the present invention also provides a method for manufacturing the aforementioned carrier substrate 11 The method includes:
Step S21: preparing a crystal ingot using crystal material powder with a particle size of 01 to 1 μm;
Step S22: cutting and grinding the crystal ingot to obtain a pre-processed substrate;
Step S23: polishing the pre-processed substrate to obtain the carrier substrate.

In Step S21, the crystal material powder may be a polycrystalline material such as polycrystalline magnesium aluminum spinel. For example, first forming a green body from the polycrystalline material powder via Cold-Isostatically-Pressed (CIP), and then processing the green body into a crystal ingot through Hot Isostatically Pressed (HIP). The CIP temperature is 1400-1500° C., and the pressing pressure is 10000-100000 psi (pounds-force per square inch). The HIP temperature is 1650-1850° C., with ambient pressure of 150-250 MPa. In Step S22, the pre-processed substrate preferably has a thickness of 250-300 μm, and the grinding uses SiC or B4C powder with a grain size of 1200-1500 mesh. In Step S23, the surface to be bonded to the piezoelectric layer is polished. The polished surface (ie, main support surface 111) has a surface roughness Sa≤ 0.6 nm and a total thickness variation (TTV)≤2 μm. The resulting carrier substrate 11 has a final thickness of 200-250 μm.

That is, in some embodiments, the TTV of the main support surface 111 of the carrier substrate 11 is less than or equal to 2 μm. In some embodiments, the surface roughness Sa of the main support surface 111 is less than or equal to 0.6 nm.

The method for manufacturing the carrier substrate 11 provided in this embodiment enables the fabrication of a carrier substrate that maintains suitable strength even when thin, thus ensuring production efficiency and improving product yield.

In some embodiments, the carrier substrate manufacturing method of the first embodiment can be incorporated into the method of the second embodiment. For example, in Step S32, both opposing surfaces of the cut substrate may be polished, and then the surface that will become the back surface 112 of the carrier substrate 11 is subjected to sandblasting to achieve the desired surface roughness, thereby reducing warpage.

Alternatively, in other embodiments, the carrier substrate 11 may be obtained by polishing only the surface intended for bonding to the piezoelectric layer in step S32. This embodiment is not limited in this regard.

When the carrier substrate manufacturing method of the first embodiment is combined with the method of the second embodiment, the resulting carrier substrate 11 can exhibit the same effects described in the first embodiment, including control of TTV, surface roughness Sz, warpage, and transmittance.

For example, in some embodiments, the TTV of the main support surface 111 of the carrier substrate 11 may be less than 1 μm.

In some embodiments, the warpage of the carrier substrate 11 is less than or equal to 200 μm.

In some embodiments, the transmittance of the carrier substrate 11 in the wavelength range of 240 to 780 nm is less than 9%. Specifically, the transmittance in the wavelength range below 550 nm is less than 0.1%, thereby facilitating alignment in subsequent fabrication processes.

In some embodiments, the surface roughness Sz of the back surface 112 of the carrier substrate 11 is greater than or equal to 3 μm, and the surface roughness Sa of the back surface 112 is greater than or equal to 0.2 μm. This not only enables lower warpage, but also effectively reflects and scatters bulk acoustic waves, suppressing noise.

In some embodiments, the surface roughness Sz of the back surface 112 of the carrier substrate 11 is greater than or equal to the average grain size of the carrier substrate 11. For example, if the average grain size of the carrier substrate 11 is 3 μm, the surface roughness Sz of the back surface 112 is greater than or equal to 3 μm. In some embodiments, the thickness of the carrier substrate 11 is greater than or equal to twice the maximum grain size. For example, if the maximum grain size is 60 μm, the thickness of the carrier substrate 11 is greater than or equal to 120 μm.

Referring to FIG. 3, the present embodiment also provides a composite substrate 10 comprising a piezoelectric layer 12 and the carrier substrate 11 as described in the second embodiment. The piezoelectric layer 12 is disposed on the carrier substrate 11 and is specifically bonded to the main support surface 111 of the carrier substrate 11. The bonding may be achieved directly via van der Waals forces. The piezoelectric layer 12 may be composed of lithium tantalate or lithium niobate. Because the carrier substrate 11 features enhanced mechanical strength and is less prone to chipping, the composite substrate 10 exhibits higher yield and improved thermal dissipation due to the reduced thickness of the carrier substrate 11.

The composite substrate 10 may be formed by direct bonding of the carrier substrate 11 and the piezoelectric layer 12. Alternatively, the bonding surfaces of the carrier substrate 11 and the piezoelectric layer 12 may be subjected to surface activation followed by room-temperature vacuum bonding. Following surface activation, the atoms at the surfaces of the carrier substrate 11 and piezoelectric layer 12 form covalent bonds, resulting in a high bonding strength and a nearly seamless integration, thus yielding a composite substrate 10 of superior quality.

In some embodiments, after bonding the carrier substrate 11 and the piezoelectric layer 12, the piezoelectric layer 12 may be thinned and polished to obtain a piezoelectric film. The thickness of the piezoelectric layer 12 may be in the range of 0.5 to 3.5 μm, depending on the target frequency band. The piezoelectric layer 12 may include a principal surface 121 opposite to the carrier substrate 11. After thinning and polishing, electrodes can be fabricated directly on the principal surface 121, eliminating the need for thinning the carrier substrate 11, thereby reducing processing steps and conserving material.

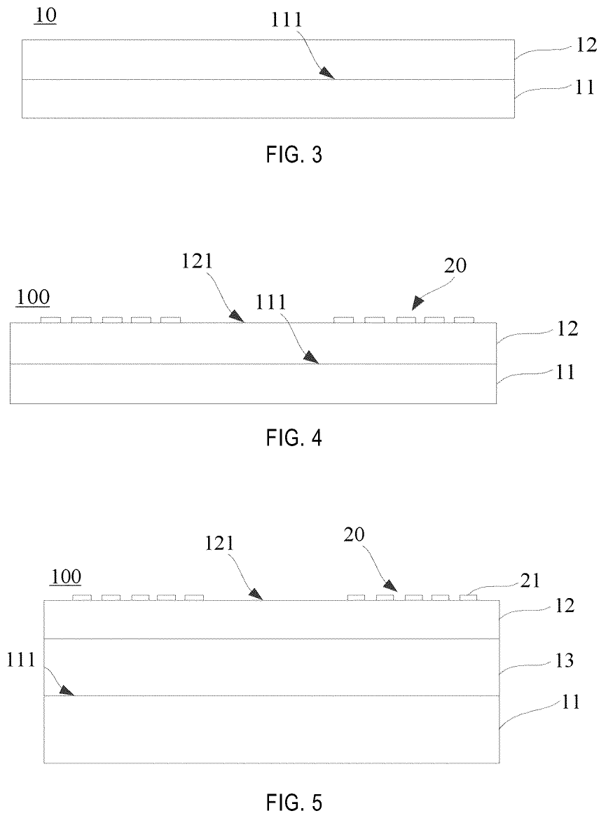

Referring to FIG. 4, the present embodiment further provides an electronic device 100, which includes the carrier substrate 11 or the composite substrate 10 described above. In some embodiments, the electronic device 100 may further include an electrode 20 disposed on the principal surface 121. The electrode 20 may include an IDT electrode 21 (interdigital transducer). The electronic device 100 may be, for example, a SAW (Surface Acoustic Wave) device Due to the higher strength of the carrier substrate 11, the device is less susceptible to chipping, which results in higher manufacturing yield. Furthermore, the thinner carrier substrate 11 contributes to enhanced thermal dissipation performance of the electronic device 100.

In some embodiments, in the electronic device 100, the grain density of the carrier substrate 11 is greater than or equal to 20000 grains/mm², and the thickness of the carrier substrate 11 is less than or equal to 250 μm.

Table 2 presents the noise suppression results of the electronic device 100 fabricated from the carrier substrates 11 of Experiments Nos. 1 to 18 in Table 1. The Noise Suppression Ratio (NSR) is positively correlated with suppression effectiveness, where 100% indicates complete noise elimination. The data in Table 2 are derived from yield tests performed in specified regions of the sample under test (ie, electronic device 100). For example, when all 21 numbered test areas (1-21) shown in FIG. 9 pass the yield test, the NSR is determined to be 100%. The grayish regions in FIG. 9 represent the piezoelectric layer 12 of the electronic device 100.

TABLE 2

| Experimental No. | NSR (%) |
|---|---|
| 1 | 85.0% |
| 2 | 85.0% |
| 3 | 85.0% |
| 4 | 95.4% |
| 5 | 95.4% |
| 6 | 95.4% |
| 7 | 96.7% |
| 8 | 96.7% |
| 9 | 96.7% |
| 10 | 100.0% |
| 11 | 100.0% |
| 12 | 100.0% |
| 13 | 100.0% |
| 14 | 100.0% |
| 15 | 100.0% |
| 16 | 100.0% |
| 17 | 100.0% |
| 18 | 100.0% |

As evidenced by Tables 1 and 2, it can be concluded that, for Experiments Nos. 1-3 with the grain density around 200 grains/mm², the limited grain boundary volume (˜6%) results in incomplete bulk wave reflection during filter operation, causing measurable noise degradation. For Experiments Nos. 4-6 with the grain density around 1000 grains/mm² and the increased grain boundary volume (≥8%) achieves near-complete bulk wave reflection, though minor noise loss persists. For Experiments Nos. 10-18 with grain densities above 20000 grains/mm², the grain boundary volume is sufficiently large to achieve complete reflection of bulk waves, effectively eliminating noise losses. The underlying mechanism reveals that bulk waves undergo energy attenuation at grain boundaries. When the carrier substrate 11 contains sufficient grain boundaries, bulk wave propagation is entirely suppressed, thereby eliminating noise.

Referring to FIG. 5, another embodiment of the present invention provides an electronic device 100 (composite substrate 10) further comprising an intermediate layer 13 disposed between the piezoelectric layer 12 and the carrier substrate 11. The acoustic velocity of the intermediate layer 13 is lower than that of the piezoelectric layer 12, ie, bulk waves propagate more slowly in the intermediate layer 13 compared to the piezoelectric layer 12. By introducing a low acoustic velocity intermediate layer 13, the phase velocity of acoustic waves can be reduced, concentrating energy within the slower medium (the intermediate layer 13), which helps minimize loss and increase the Q value.

In some embodiments, the intermediate layer 13 comprises silicon oxide, silicon oxynitride, tantalum oxide, or any materials primarily composed thereof. In some embodiments, the intermediate layer is made of silicon oxide, and the piezoelectric layer 12 is composed of lithium tantalite. Since lithium tantalate exhibits a negative temperature coefficient in its elastic constant and silicon dioxide exhibits a positive one, the overall absolute value of the TCF (temperature coefficient of frequency) in the acoustic wave device can be reduced. Furthermore, the intrinsic acoustic impedance of silicon dioxide is lower than that of lithium tantalate, which can enhance the electromechanical coupling coefficient of the electronic component.

In some embodiments, the thickness of the intermediate layer 13 is greater than or equal to 0.5\, where A is the wavelength of the acoustic wave determined by the pitch of the IDT electrodes 21. Specifically, the thickness of the intermediate layer 13 may range from 0.6A to 0.8A In some embodiments, the thickness of the piezoelectric layer 12 is less than or equal to 2A, and more specifically, less than 1λ In one specific example, A is 225 μm, the piezoelectric layer 12 has a thickness between 0.1 2 and 1A, and the intermediate layer 13 has a thickness of 0.6A.

The electronic device 100 provided in this embodiment may be packaged using a CSP (Chip Scale Package) or WLP (Wafer Level Package) approach.

### Third Embodiment

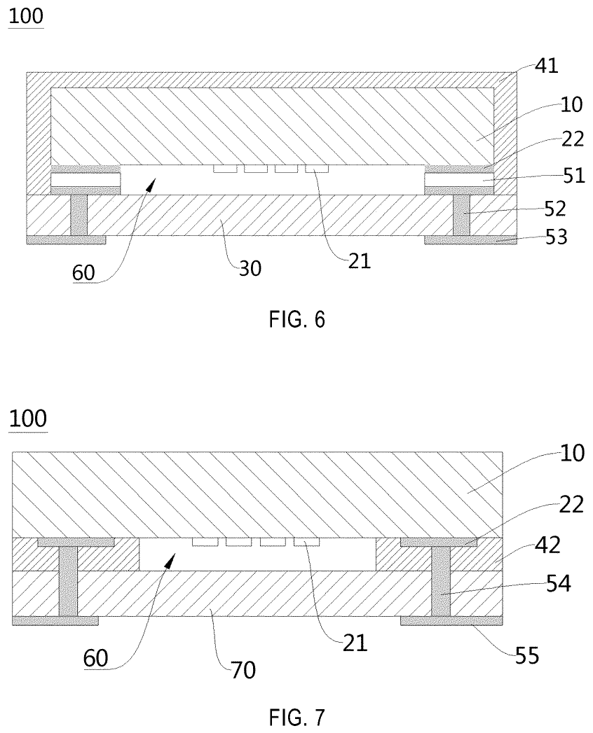

Referring to FIG. 6, a schematic cross-sectional view of an electronic device 100 with CSP packaging is shown. The electronic device 100 comprises a component (including the composite substrate 10 and electrodes 20), a package substrate 30, a first sealing structure 41, and a first external terminal electrode 53. The package substrate 30 is disposed opposite the surface of the component where the electrode 20 is formed (ie, the principal surface 121 of the piezoelectric layer 12), forming a gap 60 between the package substrate 30 and the principal surface 121. The first sealing structure 41 is located on the side of the package substrate 30 facing the component, covering the side and back of the component opposite the package substrate 30, thereby sealing the gap 60 and the component. The electrode 20 includes an electrode pad 22 electrically connected to the IDT electrode 21. The electrode pad 22 is electrically connected to a first conductive portion 52 in a wiring pattern on the package substrate 30 via a bump 51. The first conductive portion 52 is further connected to the first external terminal electrode 53 on the side of the package substrate 30 opposite the component, enabling electrical connection between the electronic device 100 and external devices via the external terminal electrode 53.

The materials for the package substrate 30 and the first sealing structure 41 may be selected from those commonly used in CSP packages. The electrode pad 22, bump 51, first conductive portion 52, and first external terminal electrode 53 are all made of highly conductive materials, and the present embodiment is not limited to the materials mentioned above.

### Fourth Embodiment

Referring to FIG. 7, a schematic view of another electronic device 100 using Wafer-Level Packaging) structure is provided. The electronic device 100 comprises a component (including the composite substrate 10 and electrodes 20), a lid 70, a second sealing structure 42, and a second external terminal electrode. The lid 70 is disposed opposite the surface of the component where the electrodes 20 are located (ie, the principal surface 121 of the piezoelectric layer 12), and a gap 60 is formed between the lid 70 and the principal surface 121. The electrode 20 includes an electrode pad 22 electrically connected to the IDT electrode 21. The region of the principal surface 121 where the IDT electrodes 21 are located is referred to as the active area. The second sealing structure 42 is disposed between the lid 70 and the component, surrounding the active area and enclosing the electrode pad 22 to seal the component A second external terminal electrode 55 is formed on the surface of the lid 70 opposite the component and is connected to the electrode pad 22 via a second conductive portion 54 passing through the lid 70 and the second sealing structure 42, thereby enabling electrical connection between the electronic device 100 and external devices through the second external terminal electrode 55.

The materials for the lid 70 and the second sealing structure 42 may be selected from those used in WLP structure. The electrode pad 22, second conductive portion 54, and second external terminal electrode 55 are all made of highly conductive materials, and the present embodiment is not limited thereto.

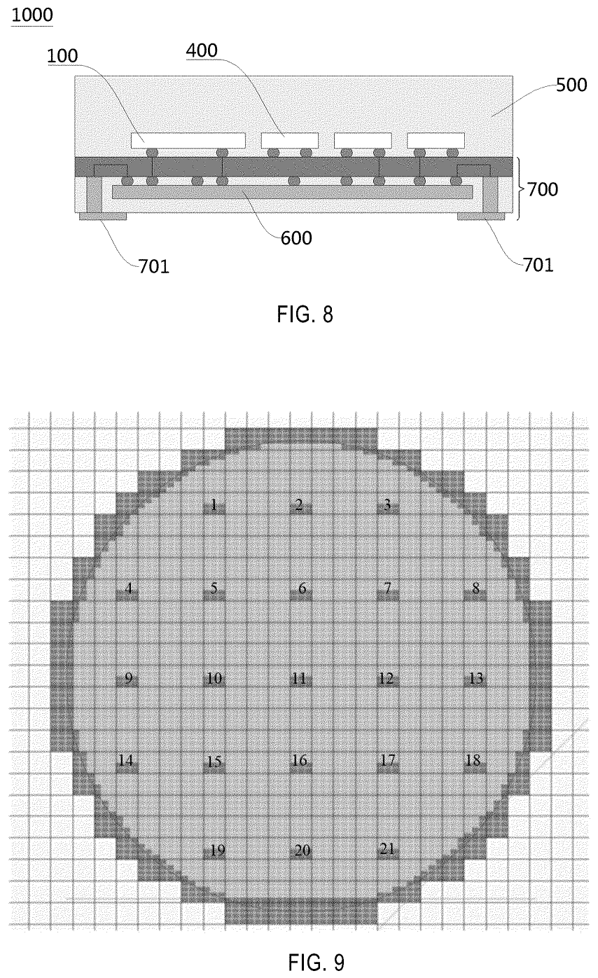

Referring to FIG. 8, the invention further provides a module 1000 comprising a wiring substrate 700, a plurality of external connection terminals 701, an integrated circuit component 600, an electronic device 100 (including the composite substrate 10), an inductor 400, and a sealing part 500. The external connection terminals 701 are formed on one surface of the wiring substrate 700 and are mounted to the main board of a predetermined mobile communication terminal. The integrated circuit component 600 (IC) is mounted inside the wiring substrate 700 and includes a switching circuit and a low-noise amplifier. The electronic device 100 is mounted on the main surface of the wiring substrate 700. The inductor 400 is used for impedance matching, for example, as an integrated passive device (IPD). The sealing part 500 seals the multiple electronic components, including the electronic device 100, on the wiring substrate 700.

The module 1000 provided in this embodiment includes the electronic device 100, which comprises the carrier substrate 11 and thus exhibits the same advantages as the carrier substrate 11 Details are omitted for brevity.

The foregoing description merely represents preferred embodiments of the present invention and is not intended to limit the invention in any way. Although the invention has been disclosed through the above embodiments, those skilled in the art may make minor modifications or equivalent changes without departing from the scope of the invention All such modifications, equivalent alterations, and improvements shall fall within the scope of the present invention as defined by its technical essence. Of course, the present invention is not limited to the embodiments described above, but rather encompasses all embodiments capable of achieving the objectives of the invention. It should be understood that the present invention includes all implementations that achieve the objectives described herein, and is not restricted solely to the specific embodiments disclosed.

Although various aspects of some embodiments have been described, it will be readily apparent to those skilled in the art that various modifications, improvements, and enhancements may be made. Such modifications, improvements, and enhancements are intended to be part of the invention and fall within the scope of this disclosure.

It should be understood that the embodiments of the methods and devices described herein are not limited to the configurations and arrangements illustrated or described above. The methods and devices may be realized in other forms and may be implemented or carried out in various ways.

The specific examples provided are for illustrative purposes only and are not intended to be limiting in any way.

The expressions and terms used in this disclosure are for the purpose of illustration and should not be construed as limiting. Terms such as “comprise,” “include,” “have,” “contain,” and variations thereof are intended to include the items listed thereafter as well as equivalents and additional items.

References to “or” are intended to be inclusive, meaning that any of the listed terms may apply individually, in combination, or collectively.

Directional expressions such as front, back, top, bottom, left, right, vertical, horizontal, inside, and outside are used merely for the sake of descriptive convenience. Such expressions do not restrict the components of the invention to any particular spatial position or orientation Accordingly, the above descriptions and drawings are merely illustrative in nature.

What is claimed is:

1. A substrate comprising a carrier substrate which is formed of a polycrystalline material, wherein the carrier substrate has a grain density of greater than or equal to 1000 grains/mm², and a grain boundary volume ratio of 8% to 40%.

2. The substrate according to claim 1, wherein the carrier substrate has a thickness of less than or equal to 300 μm.

3. The substrate according to claim 1, wherein the carrier substrate has a flexural strength of greater than or equal to 180 MPa.

4. The substrate according to claim 1, wherein the carrier substrate includes a material selected from the group consisting of polycrystalline magnesium aluminum spinel, polycrystalline sapphire, polycrystalline aluminum nitride, polycrystalline magnesium oxide, and polycrystalline quartz.

5. The substrate according to claim 1, wherein the grain density of the carrier substrate is greater than or equal to 2000 grains/mm².

6. The substrate according to claim 1, wherein the flexural strength of the carrier substrate is greater than or equal to 200 MPa.

7. The substrate according to claim 1, wherein the carrier substrate comprises a main support surface, and the main support surface has an arithmetic mean roughness of less than or equal to 0.6 nm.

8. The substrate according to claim 1, wherein the carrier substrate comprises a main support surface, and the main support surface has a total thickness variation of less than or equal to 2 μm.

9. The substrate according to claim 1, wherein the carrier substrate has a Young's modulus of greater than or equal to 250 GPa.

10. The substrate according to claim 1, wherein the carrier substrate has a transmittance of less than 9% in a wavelength band ranging from 240 to 780 nm.

11. The substrate according to claim 10, wherein the transmittance of the carrier substrate is less than 0.1% in a wavelength band below 550 nm.

12. The substrate according to claim 1, further comprising a piezoelectric layer disposed over the carrier substrate.

13. The substrate according to claim 12, wherein the piezoelectric layer has a thickness of 0.5 μm to 3.5 μm.

14. An electronic device comprising:
a substrate comprising a carrier substrate which is formed of a polycrystalline material, wherein the carrier substrate has a grain density of greater than or equal to 1000 grains/mm², and a grain boundary volume ratio of 8% to 40%;
a piezoelectric layer disposed over the carrier substrate; and
an IDT electrode provided on a principal surface of the piezoelectric layer opposite to the carrier substrate.

15. The electronic device according to claim 14, further comprising an intermediate layer disposed between the carrier substrate and the piezoelectric layer, wherein the intermediate layer has an acoustic velocity lower than that of the piezoelectric layer.

16. The electronic device according to claim 15, wherein the intermediate layer has a thickness of greater than or equal to 0.5A, where A is a wavelength of an elastic wave defined by a pitch of the IDT electrode.

17. The electronic device according to claim 14, wherein the piezoelectric layer has a thickness of less than or equal to 2A, where A is a wavelength of an elastic wave defined by a pitch of the IDT electrode.

18. The electronic device according to claim 14, wherein the grain density of the carrier substrate is greater than or equal to 2000 grains/mm².

19. The electronic device according to claim 14, wherein the carrier substrate has a thickness of less than or equal to 250 μm.

20. A module comprising a wiring substrate, a plurality of external connection terminals, an integrated circuit component, an inductor, a sealing portion, and the electronic device according to claim 14.
